(19) United States
(12) Patent Application Publication
(10) Pub. No.: US 2024/0379631 A1
(43) Pub. Date: Nov. 14, 2024

(54) LIGHT-EMITTING SUBSTRATE AND DISPLAY DEVICE

(71) Applicant: BOE Technology Group Co., Ltd., Beijing (CN)

(72) Inventors: Nianqi YAO, Beijing (CN); Jin YANG, Beijing (CN); Ce NING, Beijing (CN); Jiayu HE, Beijing (CN); Jie HUANG, Beijing (CN); Hehe HU, Beijing (CN); Kun ZHAO, Beijing (CN); Feifei LI, Beijing (CN); Zhengliang LI, Beijing (CN); Guangcai YUAN, Beijing (CN)

(21) Appl. No.: 18/691,021

(22) PCT Filed: Oct. 22, 2021
(86) PCT No.: PCT/CN2021/125854

§ 371 Date: Mar. 11, 2024

(51) Int. Cl. H01L 27/12; H01L 25/16; H01L 33/62

(52) U.S. Cl. CPC H01L 27/1248; H01L 25/167; H01L 33/62

(57) ABSTRACT

A light-emitting substrate and a display device are disclosed, the light-emitting substrate includes: a base substrate including a light-emitting region; a plurality of first pads on a side of the base substrate and in the light-emitting region, where a material of the first pads includes Cu; and an oxidation protection layer on a side of the first pads away from the base substrate, where the plurality of first pads is used for bonding connection with a plurality of light-emitting units through the oxidation protection layer, a material of the oxidation protection layer includes CuNiX, and X includes one or any combination of Al, Sn, Pb, Au, Ag, In, Zn, Bi, Mg, Ga, V, W, Y, Zr, Mo, Nb, Pt, Co or Sb.

### CROSS-REFERENCE TO RELATED APPLICATIONS

This application is a National Stage of International Application No. PCT/CN2021/125854, filed on Oct. 22, 2021, which is hereby incorporated by reference in its entirety.

### TECHNICAL FIELD

The present disclosure relates to the field of display technology, and in particular to a light-emitting substrate and a display device.

### BACKGROUND

Mini/Micro LED (light-emitting diode) light-emitting substrates have high requirements on the resistance of metal wiring, so the copper metal is often used as the wiring material. In the production process of the light-emitting substrate, Mini/Micro LED bonding, flexible printed circuit board bonding or integrated circuit bonding need to be carried out respectively.

### SUMMARY

Embodiments of the present disclosure provide a light-emitting substrate and a display device. The light-emitting substrate can avoid oxidation of pads in the light-emitting region, ensuring the reliable electrical connection between the light-emitting units and the light-emitting substrate, and improving the product yield.

A light-emitting substrate according to an embodiment of the present disclosure includes:
a base substrate, including a light-emitting region;
a plurality of first pads on a side of the base substrate and in the light-emitting region, where a material of the plurality of first pads includes Cu; and
an oxidation protection layer on a side of the plurality of first pads away from the base substrate, where the plurality of first pads are used for bonding connection with a plurality of light-emitting units through the oxidation protection layer, a material of the oxidation protection layer includes CuNiX, and X includes one or any combination of Al, Sn, Pb, Au, Ag, In, Zn, Bi, Mg, Ga, V, W, Y, Zr, Mo, Nb, Pt, Co, or Sb.

Optionally, in the above light-emitting substrate according to embodiments of the present disclosure, a thickness of the oxidation protection layer is in a range of 10 nm to 100 nm.

Optionally, in the above light-emitting substrate according to embodiments of the present disclosure, in the material of the oxidation protection layer, a sum of a mass fraction of Ni and a mass fraction of X accounts for a range of 10% to 90%.

Optionally, in the above light-emitting substrate according to embodiments of the present disclosure, a mass fraction of Cu accounts for a range of 20% to 95%, the mass fraction of Ni accounts for a range of 5% to 80%, and the mass fraction of X accounts for a range of 10% to 40%.

Optionally, in the above light-emitting substrate according to embodiments of the present disclosure, an atomic ratio of Ni to X is in a range of 2 to 4.

Optionally, in the above-mentioned light-emitting substrate according to embodiments of the present disclosure, the base substrate further includes a bonding region; and in the bonding region, the light-emitting substrate further includes a plurality of second pads on the base substrate; where the plurality of second pads are used for bonding connection with a circuit board, the plurality of second pads are in a same film layer as the plurality of first pads, and the oxidation protection layer is on a side of the plurality of second pads away from the base substrate.

Optionally, the above light-emitting substrate according to embodiments of the present disclosure further includes a first wiring layer between the plurality of first pads and the base substrate, and the first wiring layer includes a first metal sub-layer, a first wiring sub-layer and a second metal sub-layer stacked; where
the plurality of first pads are electrically connected with the second metal sub-layer, and the plurality of second pads are electrically connected with the second metal sub-layer; and
a material of the first metal sub-layer and the second metal sub-layer includes a molybdenum-niobium alloy, and a material of the first wiring sub-layer includes copper.

Optionally, the above light-emitting substrate according to embodiments of the present disclosure, in the light-emitting region, further includes: a first passivation layer between the first wiring layer and the plurality of first pads; a first planar layer between the first passivation layer and the plurality of first pads; a second planar layer on a side of the oxidation protection layer away from the base substrate, and covering a region between the plurality of first pads; and a first connecting portion on the oxidation protection layer.

Optionally, the above light-emitting substrate according to embodiments of the present disclosure, in the bonding region, further includes: a second passivation layer between the first wiring layer and the plurality of second pads; a third planar layer between the second passivation layer and the plurality of second pads; a fourth planar layer on the side of the oxidation protection layer away from the base substrate, and covering a region between the plurality of second pads; and a second connecting portion on the oxidation protection layer; where the third planar layer is in a same layer as the first planar layer, the fourth planar layer is in a same layer as the second planar layer, and the second passivation layer is in a same layer as the first passivation layer.

Optionally, in the above light-emitting substrate according to embodiments of the present disclosure, the plurality of first pads are divided into a plurality of groups of first pads, and each of the plurality of groups of first pads includes a cathode pad and an anode pad arranged in pairs; and
the light-emitting substrate further includes a second wiring layer in a same layer as the plurality of first pads; where the oxidation protection layer is on a side of the second wiring layer away from the base substrate, the second wiring layer is used for realizing a series connection or a parallel connection of the plurality of groups of first pads, and the second wiring layer is further used for being electrically connected with the first wiring layer through via holes penetrating through the first planar layer and the first passivation layer.

Optionally, the above light-emitting substrate according to embodiments of the present disclosure further includes a protection layer on a side of the oxidation protection layer away from the base substrate, the protection layer exposes the oxidation protection layer, and a material of the protection layer includes silicon nitride or silicon oxide.

Correspondingly, an embodiment of the present disclosure further provides a display device, including: the light-emitting substrate according to any one of the above items, a circuit board, and a plurality of light-emitting units;
the plurality of light-emitting units are electrically connected with the plurality of first pads of the light-emitting substrate through the oxidation protection layer, and the circuit board is electrically connected with a plurality of second pads of the light-emitting substrate through the oxidation protection layer.

Optionally, in the above display device according to embodiments of the present disclosure, the plurality of light-emitting units are Mini-LEDs or Micro LEDs.

### BRIEF DESCRIPTION OF FIGURES

In order to more clearly illustrate technical solutions in embodiments of the present disclosure, the drawings that need to be used in the description of embodiments will be briefly introduced below. Obviously, the drawings in the following description are only some embodiments of the present disclosure. Those of ordinary skill in the art can also obtain other drawings based on these drawings without making creative efforts.

FIG. 1 is a cross-sectional schematic diagram along an AA′ direction of FIG. 6.

FIG. 2A is a schematic diagram of a reflectance-wavelength variation relationship at a temperature of 150° C. after a CuNi alloy film is deposited.

FIG. 2B is a schematic diagram of a reflectance-wavelength variation relationship of an oxidation protection layer with a material of CuNiAl under different conditions according to embodiments of the present disclosure.

FIG. 3A is a surface color of a film after CuNiAl is deposited.

FIG. 3B is a surface color of a CuNiAl alloy film at 150° C. in an air atmosphere for 60 minutes.

FIG. 3C is a surface color of a CuNiAl alloy film at 260° C. in a nitrogen atmosphere for 30 minutes.

FIG. 4 is a scanning electron micrograph of stack etching of a first pad/oxidation protection layer (i.e., Cu/CuNiAl) according to embodiments of the present disclosure.

FIG. 5A is a micrograph after an oxidation protection layer is connected with a micro light-emitting diode according to embodiments of the present disclosure.

FIG. 5B is a micrograph of an interface after a micro light-emitting diode and an oxidation protection layer are separated from each other according to embodiments of the present disclosure.

FIG. 6 is a schematic top view of a light-emitting substrate according to embodiments of the present disclosure.

FIG. 7 is another schematic cross-sectional view along the AA′ direction of FIG. 6.

### DETAILED DESCRIPTION

In order to make the purpose, technical solutions and advantages of embodiments of the present disclosure clearer, the technical solutions of embodiments of the present disclosure will be clearly and completely described below in conjunction with the accompanying drawings of embodiments of the present disclosure. Apparently, the described embodiments are some of embodiments of the present disclosure, not all of them. And in the case of no conflict, embodiments in the present disclosure and the features in embodiments can be combined with each other. Based on the described embodiments of the present disclosure, all other embodiments obtained by persons of ordinary skill in the art without creative effort fall within the claimed scope of the present disclosure.

Unless otherwise defined, the technical terms or scientific terms used in the present disclosure shall have the usual meanings understood by those skilled in the art to which the present disclosure belongs. “First”, “second” and similar words used in the present disclosure do not indicate any order, quantity or importance, but are only used to distinguish different components. “Comprising” or “including” and similar words mean that the elements or items appearing before the word include the elements or items listed after the word and their equivalents, without excluding other elements or items. Words such as “connected” or “coupled” are not limited to physical or mechanical connections, but may include electrical connections, whether direct or indirect.

It should be noted that the size and shape of each figure in the drawings do not reflect the true scale, but are only intended to schematically illustrate the present disclosure. And the same or similar reference numerals represent the same or similar elements or elements having the same or similar functions throughout.

Mini-LED (sub-millimeter light-emitting diode) refers to a micro light-emitting diode with a size between 80 μm and 300 μm. When Mini-LEDs are used as pixels of a display panel to form a self-luminous display, it can achieve a higher pixel density than a small-pitch LED display. When the Mini-LEDs are used as a light source in a backlight module, an ultra-thin light source module can be made through a denser light source arrangement; and combined with the local dimming technology, the display including the Mini-LED backlight module may have a better contrast and a high dynamic lighting rendering display effect. Micro LEDs with a size of less than 80 μm can be directly used as pixels for display panels such as near-eye, wearable, and handheld terminals.

The light-emitting substrate according to the present disclosure may refer to a substrate used to provide a light source, or may refer to a substrate used for display, which is not limited thereto.

In related art, in order to complete the bonding of the Mini/Micro LEDs and the light-emitting substrate, it is necessary to set the solder paste on the pads on the light-emitting substrate to be electrically connected with the Mini/Micro LEDs, then transfer the Mini/Micro LEDs to corresponding positions on the light-emitting substrate, and then complete the fixing of the Mini/Micro LEDs and the light-emitting substrate by reflow soldering within the temperature range of 230° C. to 260° C. The bonding of the circuit board to the pads of the light-emitting substrate to be electrically connected with the circuit board is achieved by hot pressing within the temperature range of 130° C. to 150° C.

Since the bonding of Mini/Micro LEDs and the bonding of the circuit board to the light-emitting substrate require different process conditions, the bonding of Mini/Micro LEDs and the bonding of the circuit board cannot be realized simultaneously. Therefore, for example, in the case of first bonding the Mini/Micro LEDs, the pad material on the light-emitting substrate to be bonded to the circuit board is easily oxidized under the process condition corresponding to the bonding of the Mini/Micro LEDs, which cannot ensure that the circuit board has a good electrical connection with the light-emitting substrate, reducing the product yield. It can be understood that if the light-emitting substrate is first bonded to the circuit board and then bonded to the Mini/Micro LEDs, the same problem will also exist.

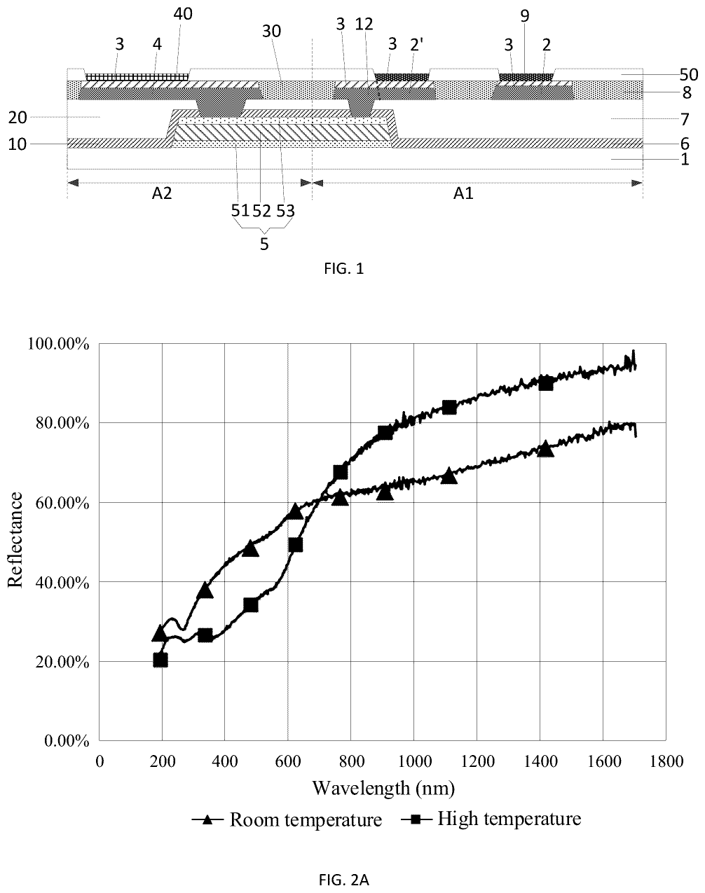

An embodiment of the present disclosure provides a light-emitting substrate that can be configured to display or provide a backlight. As shown in FIG. 1, the light-emitting substrate includes:
a base substrate 1, including a light-emitting region A1;
a plurality of first pads (2 and 2′) on a side of the base substrate 1 and in the light-emitting region A1, where a material of the first pads (2 and 2′) includes Cu; and
an oxidation protection layer 3 on a side of the plurality of first pads (2 and 2′) away from the base substrate 1, where the plurality of first pads (2 and 2′) are used for bonding connection with a plurality of light-emitting units (which is not shown in FIG. 1) through the oxidation protection layer 3. A material of the oxidation protection layer 3 includes CuNiX, where X includes one or any combination of Al, Sn, Pb, Au, Ag, In, Zn, Bi, Mg, Ga, V, W, Y, Zr, Mo, Nb, Pt, Co, or Sb.

For the above light-emitting substrate according to embodiments of the present disclosure, after the first pads (2 and 2′) are prepared using the material of Cu, the oxidation protection layer with a material including CuNiX is prepared on the first pads (2 and 2′). X includes one or any combination of Al, Sn, Pb, Au, Ag, In, Zn, Bi, Mg, Ga, V, W, Y, Zr, Mo, Nb, Pt, Co, or Sb. Ni and X have the oxidation resistance, so as to prevent a surface of the oxidation protection layer from being oxidized. In addition, in embodiments of the present disclosure, the oxidation resistance can be achieved by adding an anti-oxidation CuNiX alloy film layer on the first pads without an additional anti-oxidation process, which greatly simplifies the process flow and reduces the mass production cost. Moreover, in embodiments of the present disclosure, the CuNiX alloy film can be deposited by target material sputtering, without using the anti-oxidation process, such as Ni-Au or Copper Preservatives (e.g., organic solderability preservatives, OSP), after making pads in related art, which reduces the cost and improves productivity. Moreover, the CuNiX oxidation protection layer according to embodiments of the present disclosure has better oxidation resistance in a high temperature environment.

The light-emitting substrate according to embodiments of the present disclosure may be a display substrate or may be a backlight substrate. If the light-emitting substrate is the display substrate, the light-emitting region A1 constitutes a display region, and the light-emitting units are sub-pixels, realizing display of a picture. If the light-emitting substrate is the backlight substrate, the light-emitting region A1 is used for providing a light source to cooperate with a passive display panel to realize display.

Here, there is no limitation on the light-emitting color in the light-emitting region of the light-emitting substrate. The light-emitting region may be any one of a red light-emitting region, a green light-emitting region or a blue light-emitting region. The light-emitting substrate may include light-emitting regions of three light-emitting colors: a red light-emitting region, a green light-emitting region, and a blue light-emitting region. Of course, the light-emitting substrate may also only include a light-emitting region of one light-emitting color, e.g., only include a plurality of red light-emitting regions, or only includes a plurality of green light-emitting regions, or only includes a plurality of blue light-emitting regions. The details can be determined according to actual requirements.

The method for controlling the light-emitting regions is not limited. For example, each light-emitting region may be controlled independently, or a plurality of light-emitting regions may be controlled simultaneously.

A material of the base substrate may be a rigid material, such as glass, quartz, plastic, or a printed circuit board; or may be a flexible material, such as polyimide.

In specific implementation, in the above-mentioned light-emitting substrate according to embodiments of the present disclosure, as shown in FIG. 1, the oxidation protection layer 3 mainly plays the role of protecting the first pads (2 and 2′), so a thickness of the oxidation protection layer 3 should not be too thick to avoid increasing the difficulty of etching which cannot guarantee the pattern morphology, and it should not be too thin to avoid poor anti-oxidation performance. Therefore, considering the two factors of process realization and anti-oxidation performance, in embodiments of the present disclosure, a thickness of the oxidation protection layer 3 is set to be in a range of 10 nm to 100 nm, e.g., 10 nm, 20 nm, 30 nm, 40 nm, 50 nm, 60 nm, 70 nm, 80 nm, 90 nm, 100 nm.

The oxidation protection layer 3 can be obtained by sputtering a target material of alloy, or co-sputtering a target material of single metal, which can be selected according to actual requirements.

In specific implementation, in the above light-emitting substrate according to embodiments of the present disclosure, as shown in FIG. 1, in the material of the oxidation protection layer 3, a sum of a mass fraction of Ni and a mass fraction of X accounts for a range of 10% to 90%. The inventors have found through tests that when a mass fraction of Cu accounts for a range of 20% to 95%, the mass fraction of Ni accounts for a range of 5% to 80%, and the mass fraction of X accounts for a range of 10% to 40%, the oxidation protection layer 3 has better anti-oxidation performance.

In specific implementation, in the above light-emitting substrate according to embodiments of the present disclosure, in the oxidation protection layer with the material of CuNiX, when an atomic ratio of Ni to X is in a range of about 2 to 4, the oxidation protection layer 3 has better anti-oxidation performance.

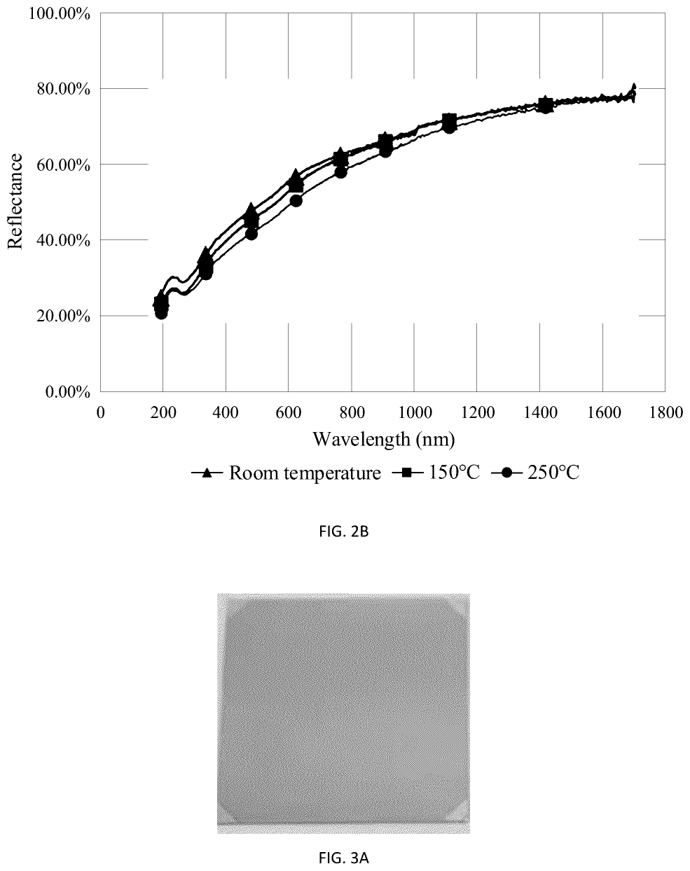

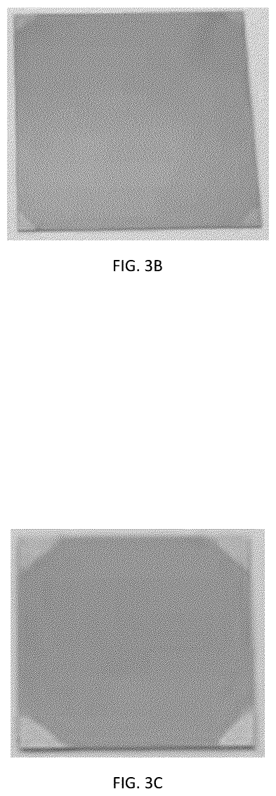

The scheme of using CuNi alloy as the oxidation protection layer is disclosed in the related art, and the oxidation condition of the metal surface can be analyzed through the reflectance test. When the film layer is oxidized, surface composition of the film layer changes, and reflectance of the film layer decreases significantly. As shown in FIG. 2A and FIG. 2B, FIG. 2A is a schematic diagram of a reflectance-wavelength variation relationship of a CuNi alloy film at 150° C. in an air atmosphere for 60 minutes after the CuNi alloy film is formed by a sputtering process at the room temperature (e.g., at 10° C.-50° C., e.g., 25° C., or 30°° C.), and FIG. 2B is a schematic diagram of a reflectance-wavelength variation relationship of the oxidation protection layer with the material of CuNiAl alloy under different conditions according to embodiments of the present disclosure, in which a reflectance variation curve of the film after the CuNiAl alloy film is formed by the sputtering process at the room temperature, a reflectance variation curve of the CuNiAl alloy film in the air at 150° C. for 60 minutes after the CuNiAl alloy film is deposited, and a reflectance variation curve of the CuNiAl alloy film in the air at 250° C. for 30 minutes after the CuNiAl alloy film is deposited are shown. It can be seen from FIG. 2A and FIG. 2B that the reflectance of the CuNi alloy film decreases significantly at 150° C., indicating that the CuNi alloy is oxidized at 150° C., while the reflectance of the CuNiAl at 150° C. and the reflectance of the CuNiAl at 250° C. in embodiments of the present disclosure do not change significantly, so CuNiAl in embodiments of the present disclosure still has better oxidation resistance at 150° C. and 250° C. As shown in FIG. 3A to FIG. 3C, FIG. 3A is a surface color of an alloy film without heat treatment after the CuNiAl alloy film is deposited, FIG. 3B is a surface color of the CuNiAl alloy film at 150° C. in the air for 60 minutes, and FIG. 3C is a surface color of the CuNiAl alloy film at 260° C. in the nitrogen atmosphere for 30 minutes. It can be seen that the surface color of the CuNiAl alloy film does not change significantly after being exposed to air at 150° C. for 60 minutes and to N₂ at 260° C. for 30 minutes, which indicates that the surface of the CuNiAl alloy film has not been oxidized. Therefore, the oxidation protection layer with the material of CuNiAl alloy according to embodiments of the present disclosure has better oxidation resistance in the high temperature environment.

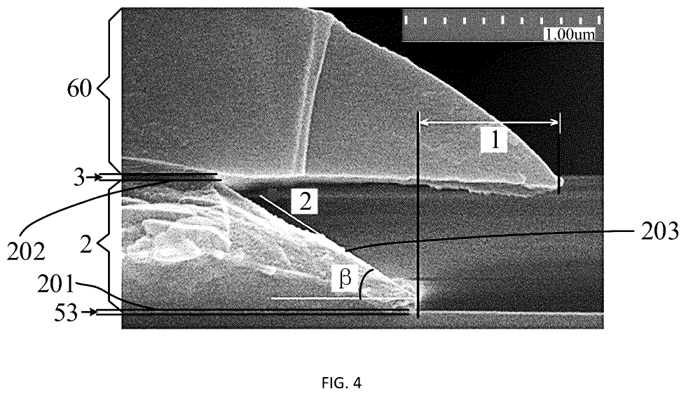

In specific implementation, in the above-mentioned light-emitting substrate according to embodiments of the present disclosure, as shown in FIG. 1, the material of the first pads (2 and 2′) includes Cu, and taking the material of the oxidation protection layer 3 being CuNiAl as an example, after simultaneously forming the pattern of the first pads (2 and 2′) and the pattern of the oxidation protection layer 3 through an etching process, the scanning electron micrograph (SEM) of the stacked structure formed by the first pads (2 and 2′) and the oxidation protection layer 3 is shown in FIG. 4. FIG. 4 shows that the bottom layer is a buffer layer (a third metal sub-layer 53 which will be introduced later), the first pads 2 made of Cu with a thickness of about 6000 Å are on the third metal sub-layer 53, the oxidation protection layer 3 made of CuNiAl alloy with a thickness of about 500 Å is on the first pads 2, and a photoresist layer 60 is on a side of the oxidation protection layer 3 away from the first pads 2. The photoresist layer 60 is used for patterning the oxidation protection layer 3. Retaining the photoresist layer 60 in the SEM is to confirm a CD Bias (represented by 1) after the first pads 2 are etched. The CD Bias is a value of a size of the first pads 2 before etching minus a size of the first pads 2 after etching, and when the CD Bias is in a range of 0.5 μm to 2 μm, the etched morphology of the first pads 2 is good. The value of the CD Bias 1 measured in the disclosure is 0.74 μm, which is in the range of 0.5 μm to 2 μm, so the etched morphology of the first pads 2 is good.

In some embodiments, the oxidation protection layer 3, the first pads 2, and the third metal sub-layer 53 are formed by the same one patterning process, that is, their respective film layers are patterned simultaneously in one wet etching process. It can be seen from FIG. 4 that there is no tip (roof structure) in the morphology of the oxidation protection layer 3 after etching, and there is no undercut or tail in the morphology of the third metal sub-layer 53 after etching. Therefore, the oxidation protection layer 3, the first pad 2 and the third metal sub-layer 53 all have good etching morphology.

As shown in FIG. 4, the first pad 2 includes a first main surface 201, a second main surface 202 opposite to the first main surface 201, and a side surface 203 connecting the first main surface 201 and the second main surface 202. The first main surface 210 is closer to the third metal sub-layer 53 than the second main surface 202, an angle β between a tangent line 2 of the side surface 203 at any point and a plane where the third metal sub-layer 53 is located determines the coverage of subsequent film layers. To avoid the problem of poor lapping of subsequent film layers (e.g., the oxidation protection layer 3), the maximum value of β is required to be in a range of 30° to 80°. If β is higher than 80°, there may be a problem of poor lapping of subsequent film layers. It can be seen from the SEM (FIG. 4) measured in embodiments of the present disclosure, β is about 33.1°, which indicates that the etching interface is good, and that the oxidation protection layer 3 added on the first pads 2 in embodiments of the present disclosure will not have the problem of poor lapping. In the subsequent deposition of the passivation layer, if β is too large, or there is a tip on the oxidation protection layer 3, a thicker passivation layer is required to cover the oxidation protection layer 3 to avoid film breakage. However, in embodiments of the present disclosure, the measured β is about 33.1°, so it will not affect the deposition of subsequent film layers (e.g., the passivation layer).

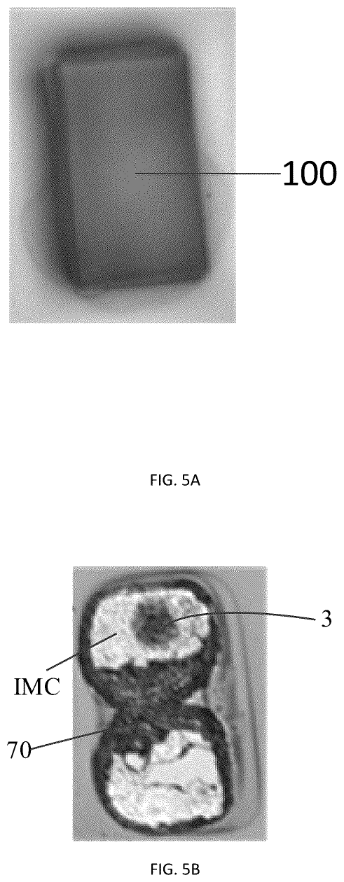

As shown in FIG. 5A and FIG. 5B, FIG. 5A is a micrograph after pins of the micro-LEDs 100 are fixedly connected with the oxidation protection layer 3 according to embodiments of the present disclosure through a solder metal 70 (such as tin), and FIG. 5B is a micrograph after the micro-LEDs 100 and the oxidation protection layer 3 in FIG. 5A are separated from each other. It can be seen that after the micro-LEDs 100 are separated from the oxidation protection layer 3, the solder metal 70 remaining on the surface of the oxidation protection layer 3 and the surface of the oxidation protection layer 3 are fixedly connected through the reflow soldering process and react with each other to form a good intermetallic compound (IMC), which has good wettability.

In specific implementation, in the above-mentioned light-emitting substrate according to embodiments of the present disclosure, as shown in FIG. 1, the base substrate 1 further includes a bonding region A2. In the bonding region A2, the light-emitting substrate further includes a plurality of second pads 4 on the base substrate. The plurality of second pads 4 are used for bonding connection with a circuit board (not shown in FIG. 1). The second pads 4 are in a same film layer as the first pads (2 and 2′). The oxidation protection layer 3 is on a side of the second pads 4 away from the base substrate 1. The fact that the second pads 4 are in the same film layer as the first pads (2 and 2′) means that the second pads 4 and the first pads (2 and 2′) are made by one patterning process. One patterning process refers to forming the required pattern through one film forming and photolithography process. One patterning process includes film formation, exposure, development, etching and stripping. The second pads 4 are in the same film layer as the first pads (2 and 2′), so that the number of patterning processes can be reduced, the manufacturing process can be simplified, and the production cost can be greatly reduced. At the same time, the oxidation protection layer 3 can further be on the side of the second pad 4 away from the base substrate 1, so the surface of the second pads 4 also has the oxidation resistance. Therefore, during the manufacturing process of the light-emitting substrate, the second pads 4 in the bonding region A2 will not be oxidized, so that the problem of oxidation in the process of manufacturing the light-emitting substrate can be avoided, and the stability of the second pads 4 can be improved.

In specific implementation, as shown in FIG. 1, the above-mentioned light-emitting substrate according to embodiments of the present disclosure further includes a first wiring layer 5 between the first pads (2 and 2′) and the base substrate 1. The first wiring layer 5 includes a first metal sub-layer 51, a first wiring sub-layer 52 and a second metal sub-layer 53 stacked. The first pads (2 and 2′) and the second pads 4 are electrically connected with different conductive patterns/conductive lines in the second metal sub-layer 53, respectively.

A material of the first metal sub-layer 51 and the second metal sub-layer 53 includes a molybdenum-niobium alloy, and the molybdenum-niobium alloy has adhesiveness and enhances the adhesion between the first wiring layer 5 and the base substrate 1. In some cases, in order to prevent the overall area of the first wiring layer 5 from being too large, causing the base substrate 1 to be subjected to excessive stress and resulting in fragmentation, a buffer layer can be provided between the base substrate 1 and the first wiring layer 5 to relieve the stress. In addition, the first metal sub-layer 51 with the material including the molybdenum-niobium alloy can also enhance the adhesion between the first wiring layer 5 and the buffer layer, and a material of the buffer layer is, e.g., silicon nitride. At the same time, the second metal sub-layer 53 with the material including the molybdenum-niobium alloy is connected with the first pads 2′. The molybdenum-niobium alloy has adhesiveness, which can ensure that the first wiring layer 5 and the first pads 2′ are connected firmly, and the molybdenum-niobium alloy has conductivity, which can ensure the conductivity between the first pads 2′ and the first wiring layer 5. A material of the first wiring sub-layer 52 can include copper, and copper has good conductivity, which can ensure the electrical connection between the film layers. The small resistance of copper can reduce the current loss during operation, and the low price of copper can reduce the production cost of the array substrate. In addition, the second metal sub-layer 53 with the material including the molybdenum-niobium alloy can protect the copper of the first wiring sub-layer 52 and prevent the copper from being oxidized. The material of the first wiring sub-layer 52 can include copper, and copper has good conductivity, which can ensure the electrical connection between the film layers. The small resistance of copper can reduce the current loss during operation, and the low price of copper can reduce the production cost of the light-emitting substrate.

In a specific implementation, as shown in FIG. 1, a thickness of the first wiring sub-layer 52 may be in a range of 1 μm to 3 μm.

In a specific implementation, as shown in FIG. 1, a thickness of the first pads (2 and 2′) may be in a range of 1000 angstroms to 8000 angstroms, and a thickness of the oxidation protection layer 3 may be in a range of 500 angstroms to 1500 angstroms.

In specific implementation, as shown in FIG. 1, the film layer of the second pads 4 arranged in the same layer as the first pads (2 and 2′) is taken as an example. Of course, the second pads 4 can also be arranged only in the same layer as the first wiring layer 5, or the second pads 4 adopts a film layer arranged in the same layer as the first wiring layer 5 and the first pads (2 and 2′).

In specific implementation, in the above-mentioned light-emitting substrate according to embodiments of the present disclosure, as shown in FIG. 1, in the light-emitting region A1, the light-emitting substrate further includes: a first passivation layer 6 between the first wiring layer 5 and the first pads (2 and 2′), a first planar layer 7 between the first passivation layer 6 and the first pads (2 and 2′), a second planar layer 8 on a side of the oxidation protection layer 3 away from the base substrate 1, covering a region between the plurality of first pads (2 and 2′), and a first connecting portion 9 on the oxidation protection layer 3.

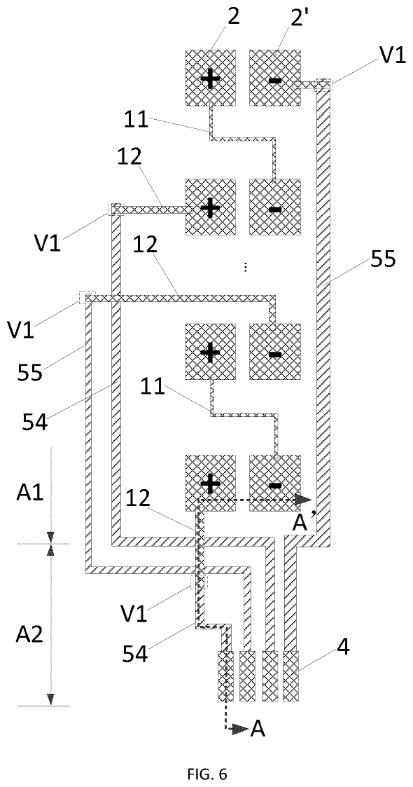

As shown in FIG. 6, FIG. 1 is a schematic cross-sectional view along the AA′ direction in FIG. 6, and the first wiring layer 5 may include an anode wiring 54 and a cathode wiring 55 (not shown in FIG. 1). Both the anode wiring 54 and the cathode wiring 55 are arranged using the first metal sub-layer 51, the first wiring sub-layer 52 and the second metal sub-layer 53 stacked. In order to reduce the voltage drop (IR Drop), the thickness of the first wiring sub-layer 52 is greater than the thickness of the first pads (2 and 2′), and the thickness of the first wiring sub-layer 52 is positively related to the product size of the Mini-LED backplane. The first metal sub-layer 51, the first wiring sub-layer 52 and the second metal sub-layer 53 can be fabricated in sequence by using a sputtering process, and the second metal sub-layer 53 can protect the first wiring sub-layer 52 and prevent the surface of the first wiring sub-layer 52 from being oxidized.

During specific implementation, as shown in FIG. 1, the first passivation layer 6 includes a portion between the anode wiring 54 and the cathode wiring 55, for separating adjacent wirings to avoid incorrect electrical connection between adjacent wirings. The material of the first passivation layer 6 can be the silicon nitride, silicon oxide, silicon oxynitride, etc. The first planar layer 7 covers the region between the anode wiring 54 and the cathode wiring 55, and the first planar layer 7 may be an organic film, which is used to fill the gap region between the wirings and avoid large step differences in subsequent processes to ensure that the displacement of the light-emitting unit does not occur when the light-emitting unit is bonded, improving the flatness of the array substrate. At the same time, the first planar layer 7 can also play an insulating role.

As shown in FIG. 1, the material of the first connecting portion 9 on the oxidation protection layer 3 is a solder metal material, such as the tin, tin-copper alloy, tin-silver alloy, copper, etc.

As shown in FIG. 1, the thickness of the first passivation layer 6 may be in a range of 1000 angstroms to 4000 angstroms.

In specific implementation, in the above-mentioned light-emitting substrate according to embodiments of the present disclosure, as shown in FIG. 1, in the bonding region A1, the light-emitting substrate further includes: a second passivation layer 10 between the first wiring layer 5 and the second pads 4, a third planar layer 20 between the second passivation layer 10 and the second pads 4, a fourth planar layer 30 on the side of the oxidation protection layer 3 away from the base substrate 1, and covering a region between the plurality of second pads 4, and a second connecting portion 40 on the oxidation protection layer 3.

The third planar layer 20 and the first planar layer 7 are in the same layer, and can form an integral structure. A material of the third planar layer 20 can be an organic material, e.g., the resin used for planarization to facilitate the production of subsequent processes (e.g., the first pads 2, the second pads 4, etc.). The fourth planar layer 30 and the second planar layer 8 are in the same layer, and can form an integral structure. A material of the fourth planar layer 30 can be an organic material, e.g., the resin used for planarization to facilitate the production of subsequent processes (e.g., the protection layer 50). The second passivation layer 10 and the first passivation layer 6 are in the same layer, and can form an integral structure, and a material of the second passivation layer 10 can be the silicon oxynitride, silicon nitride, silicon oxide, etc.

As shown in FIG. 1, a thickness of the second passivation layer 10 may be in a range of 1000 angstroms to 9000 angstroms.

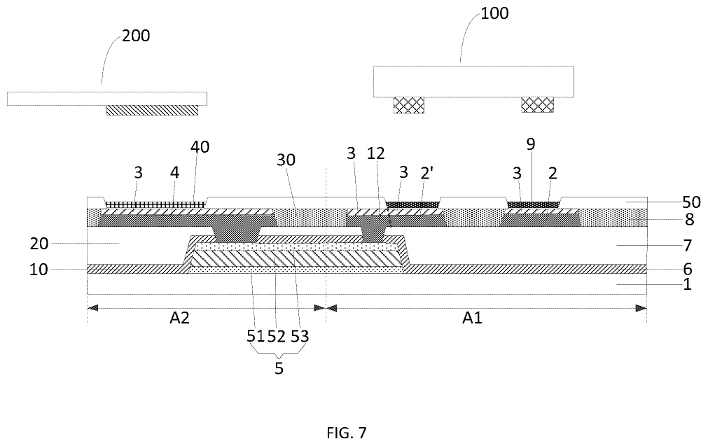

In a specific implementation, the above-mentioned light-emitting substrate according to embodiments of the present disclosure may further include a plurality of light-emitting units, and the light-emitting units may include micro light-emitting diodes 100 as shown in FIG. 7. It should be noted that since the micro light-emitting diode 100 includes an anode pin and a cathode pin, one micro light-emitting diode 100 needs to be bonded through two first pads. The above plurality of first pads can be divided into a plurality of groups of first pads. Each of the plurality of groups of first pads is used to bond one micro light-emitting diode, and includes a cathode pad and an anode pad arranged in pairs. A first pad bonded to the cathode pin of the micro light-emitting diode is called the cathode pad, and a first pad bonded to the anode pin of the micro light-emitting diode is called the anode pad. As shown in FIG. 6, each of the plurality of groups of first pads includes a cathode pad 2′ and an anode pad 2 arranged in pairs, and the cathode pad 2′ and the anode pad 2 include the same film layer structure.

As shown in FIG. 7, the micro light-emitting diode 100 is bonded to the cathode pad 2′ and the anode pad 2 through the first connecting portion 9 and the oxidation protection layer 3. Since the material of the first connecting portion 9 generally includes the metal of nickel, the material of the oxidation protection layer 3 according to embodiments of the present disclosure is CuNiX. Ni in the oxidation protection layer 3 can be combined with Ni in the first connecting portion 9 to improve the adhesion between the first connecting portion 9 and the oxidation protection layer 3.

As shown in FIG. 7, a circuit board 200 is bonded and connected with the second pads 4 through the second connecting portion 40 and the oxidation protection layer 3. The circuit board 200 includes a printed circuit board, a flexible circuit board, an integrated circuit chip, etc. A material of the second connecting portion 40 may be thermosetting glue or anisotropic conductive glue.

In specific implementation, in the above-mentioned light-emitting substrate according to embodiments of the present disclosure, as shown in FIG. 1 and FIG. 6, the plurality of first pads (2 and 2′) are divided into a plurality of groups of first pads, and each of the plurality of groups of first pads includes a cathode pad 2′ and an anode pad 2 arranged in pairs.

The light-emitting substrate further includes a second wiring layer in a same layer as the plurality of first pads (2 and 2′). The oxidation protection layer 3 is on a side of the second wiring layer away from the base substrate 1. The second wiring layer is used for realizing a series connection or a parallel connection of the plurality of groups of first pads (2 and 2′), and the second wiring layer is further used for being electrically connected with the first passivation layer 6 through via holes that penetrate through the first planar layer 7 and the first passivation layer 6.

As shown in FIG. 1 and FIG. 6, the second wiring layer includes a wiring 11 and a wiring 12. As shown in FIG. 1, the wiring 12 and the first pad 2′ are of an integral structure, and the wiring 12 and the first pad 2′ are separated by a dotted line in FIG. 1.

The specific connection method of the above plurality of groups of first pads is not limited. In FIG. 6, two adjacent groups of first pads are connected in series as an example for illustration. As shown in FIG. 1 and FIG. 6, the plurality of first pads (2 and 2′) can be divided into a plurality of groups of first pads, and each of the plurality of groups of first pads is used to bond one micro light-emitting diode, and includes the cathode pad 2′ and the anode pad 2 arranged in pairs. The first wiring layer 5 may include the anode wiring 54 and the cathode wiring 55. The first pads of two adjacent groups of first pads are connected in series through a wiring 11. As shown in FIG. 1 and FIG. 6, in the two adjacent groups of first pads connected in series, an anode pad 2 of one group of first pads is electrically connected with a wiring 12, and the wiring 121 is electrically connected with the anode wiring 54 through the via hole V1 penetrating through the first passivation layer 6 and the first planar layer 7. The anode wiring 54 is electrically connected with one second pad 4 through a via hole (not shown in FIG. 1) penetrating through the first passivation layer 6 and the first planar layer 7. A cathode pad of the other group of first pads is electrically connected with another wiring 12, and this another wiring 12 is electrically connected with the cathode wiring 55 through another via hole V1 penetrating through the first passivation layer 6 and the first planar layer 7. The cathode wiring 55 is electrically connected with another second pad 4 through a via hole (not shown in FIG. 1) penetrating through the first passivation layer 6 and the first planar layer 7. In FIG. 6, the cathode pad 2′, the anode pad 2, the second pad 4, the wiring 11, and the wiring 12 are in the same layer. The same filling pattern is used to indicate the cathode pad 2′, the anode pad 2, the second pad 4, the wiring 11, and the wiring 12 that are in the same layer. The anode wiring 54 and the cathode wiring 55 are in the same layer. The same filling pattern is used to indicate the anode wiring 54 and the cathode wiring 55 that are in the same layer.

It can be understood that, in the present disclosure, the driving method for the light-emitting substrate is not limited. As shown in FIG. 6, the light-emitting substrate drives the light-emitting units in a passive manner, or may provide signals to the light-emitting units through a drive circuit including the thin film transistor(s), or may provide signals to the light-emitting units through a microchip.

When the signal is provided to the light-emitting unit through the microchip, each microchip includes a plurality of pins, and the light-emitting substrate further includes third pads in the light-emitting region for bonding connection with the pins of the microchip. The structures of the third pads are similar to that of the first pads, and can be manufactured using the same film layer structure as the first pads. The plurality of light-emitting units can be divided into a plurality of lamp regions, each lamp region includes at least one light-emitting unit, and each microchip is used to drive the light-emitting unit in at least one lamp region to emit light.

In specific implementation, as shown in FIG. 1 and FIG. 7, the above-mentioned light-emitting substrate according to embodiments of the present disclosure further includes a protection layer 50 on a side of the oxidation protection layer 3 away from the base substrate 1. The protection layer 50 exposes the oxidation protection layer 3, and a material of the protection layer 50 may include silicon oxynitride, silicon nitride or silicon oxide.

In specific implementation, in the above-mentioned light-emitting substrate according to embodiments of the present disclosure, the light-emitting unit can be a mini light-emitting diode (referred to as: Mini-LED), also known as a sub-millimeter light-emitting diode, or a micro light-emitting diode (referred to as: Micro LED).

When the light-emitting substrate according to embodiments of the present disclosure is used as a backlight source, the light-emitting units can use Mini-LEDs, and the size and pitch of the Mini-LEDs are small, not only can the number of local dimming zones (Local Dimming Zones) be made more detailed to achieve a high-dynamic range (HDR) to present a high-contrast effect, but also can shorten the optical distance (OD) to reduce the thickness of the whole machine to meet the thinning requirements.

Based on the same inventive concept, an embodiment of the present disclosure further provides a display device, including: the above-mentioned light-emitting substrate, the circuit board and the plurality of light-emitting units according to embodiments of the present disclosure. The light-emitting unit can adopt the Mini-LED or Micro LED.

The plurality of light-emitting units are electrically connected with the plurality of first pads of the light-emitting substrate through the oxidation protection layer, and the circuit board is electrically connected with the plurality of second pads of the light-emitting substrate through the oxidation protection layer.

The display device has the characteristics of high contrast, good brightness, high color reproduction and the like. The display device may be a rigid display device or a flexible display device (i.e., bendable or foldable). The display device may be any product or component with a display function such as a mobile phone, a tablet computer, a television, a monitor, a notebook computer, a digital photo frame, a navigator, and the like. The other essential components of the display device should be understood by those of ordinary skill in the art, and will not be repeated here, nor should they be regarded as limitations on the present disclosure. The problem-solving principle of the display device is similar to that of the above-mentioned light-emitting substrate, so the implementation of the display device can refer to the implementation of the above-mentioned light-emitting substrate, and repeated descriptions will not be repeated here.

For the light-emitting substrate and display device according to embodiments of the present disclosure, after the first pads are prepared using the material of Cu, the oxidation protection layer with the material including CuNiX is prepared on the first pads. X includes one or any combination of Al, Sn, Pb, Au, Ag, In, Zn, Bi, Mg, Ga, V, W, Y, Zr, Mo, Nb, Pt, Co, or Sb. Ni and X have the oxidation resistance, so as to prevent the surface of the oxidation protection layer from being oxidized. In addition, in embodiments of the present disclosure, the oxidation resistance can be achieved by adding an anti-oxidation CuNiX alloy film layer on the first pads without an additional anti-oxidation process, which greatly simplifies the process flow and reduces the mass production cost. Moreover, in embodiments of the present disclosure, the CuNiX alloy film can be deposited by target material sputtering, which improves the feasibility of mass production. Moreover, the CuNiX oxidation protection layer according to embodiments of the present disclosure has better oxidation resistance in a high temperature environment.

Obviously, those skilled in the art can make various changes and modifications to the present disclosure without departing from the spirit and scope of the present disclosure. Thus, if these modifications and variations of the present disclosure fall within the scope of the claims of the present disclosure and equivalent technologies thereof, the present disclosure also intends to include these modifications and variations.

1. A light-emitting substrate, comprising:
a base substrate, comprising a light-emitting region;
a plurality of first pads on a side of the base substrate and in the light-emitting region, wherein a material of the plurality of first pads comprises Cu; and
an oxidation protection layer on a side of the plurality of first pads away from the base substrate, wherein the plurality of first pads are used for bonding connection with a plurality of light-emitting units through the oxidation protection layer, a material of the oxidation protection layer comprises CuNiX, and X comprises one or any combination of Al, Sn, Pb, Au, Ag, In, Zn, Bi, Mg, Ga, V, W, Y, Zr, Mo, Nb, Pt, Co, or Sb.

2. The light-emitting substrate according to claim 1, wherein a thickness of the oxidation protection layer is in a range of 10 nm to 100 nm.

3. The light-emitting substrate according to claim 1, wherein in the material of the oxidation protection layer, a sum of a mass fraction of Ni and a mass fraction of X accounts for a range of 10% to 90%.

4. The light-emitting substrate according to claim 3, wherein a mass fraction of Cu accounts for a range of 20% to 95%, the mass fraction of Ni accounts for a range of 5% to 80%, and the mass fraction of X accounts for a range of 10% to 40%.

5. The light-emitting substrate according to claim 3, wherein an atomic ratio of Ni to X is in a range of 2 to 4.

6. The light-emitting substrate according to claim 1, wherein the base substrate further comprising a bonding region; and in the bonding region, the light-emitting substrate further comprises a plurality of second pads on the base substrate;
wherein the plurality of second pads are used for bonding connection with a circuit board, the plurality of second pads are in a same film layer as the plurality of first pads, and the oxidation protection layer is on a side of the plurality of second pads away from the base substrate.

7. The light-emitting substrate according to claim 6, further comprising: a first wiring layer between the plurality of first pads and the base substrate, and the first wiring layer comprises a first metal sub-layer, a first wiring sub-layer and a second metal sub-layer stacked; wherein
the plurality of first pads are electrically connected with the second metal sub-layer, and the plurality of second pads are electrically connected with the second metal sub-layer; and
a material of the first metal sub-layer and the second metal sub-layer comprises a molybdenum-niobium alloy, and a material of the first wiring sub-layer comprises copper.

8. The light-emitting substrate according to claim 7, wherein in the light-emitting region, the light-emitting substrate further comprises:
a first passivation layer between the first wiring layer and the plurality of first pads;
a first planar layer between the first passivation layer and the plurality of first pads;
a second planar layer on a side of the oxidation protection layer away from the base substrate, and covering a region between the plurality of first pads; and
a first connecting portion on the oxidation protection layer.

9. The light-emitting substrate according to claim 8, wherein in the bonding region, the light-emitting substrate further comprises:
a second passivation layer between the first wiring layer and the plurality of second pads;
a third planar layer between the second passivation layer and the plurality of second pads;
a fourth planar layer on the side of the oxidation protection layer away from the base substrate, and covering a region between the plurality of second pads; and
a second connecting portion on the oxidation protection layer; wherein
the third planar layer is in a same layer as the first planar layer, the fourth planar layer is in a same layer as the second planar layer, and the second passivation layer is in a same layer as the first passivation layer.

10. The light-emitting substrate according to claim 8, wherein the plurality of first pads are divided into a plurality of groups of first pads, and each of the plurality of groups of first pads comprises a cathode pad and an anode pad arranged in pairs; and
the light-emitting substrate further comprises a second wiring layer in a same layer as the plurality of first pads; wherein the oxidation protection layer is on a side of the second wiring layer away from the base substrate, the second wiring layer is used for realizing a series connection or a parallel connection of the plurality of groups of first pads, and the second wiring layer is further used for being electrically connected with the first wiring layer through via holes penetrating through the first planar layer and the first passivation layer.

11. The light-emitting substrate according to claim 7, further comprising: a protection layer on a side of the oxidation protection layer away from the base substrate, the protection layer exposes the oxidation protection layer, and a material of the protection layer comprises silicon nitride or silicon oxide.

12. A display device, comprising: the light-emitting substrate according to claim 1, a circuit board, and the plurality of light-emitting units;
the plurality of light-emitting units are electrically connected with the plurality of first pads of the light-emitting substrate through the oxidation protection layer, and the circuit board is electrically connected with a plurality of second pads of the light-emitting substrate through the oxidation protection layer.

13. The display device according to claim 12, wherein the plurality of light-emitting units are Mini light-emitting diodes (LED) or Micro LEDs.
